(19) United States
(12) Patent Application Publication
(10) Pub. No.: US 2026/0006725 A1
(43) Pub. Date: Jan. 1, 2026

(54) AIR BEARING FOR FLEX CIRCUIT

(71) Applicant: International Business Machines Corporation, Armonk, NY (US)

(72) Inventors: Arthur J. HIGBY, Cottekill, NY (US); Lauren BOSTON, Poughkeepsie, NY (US); Philipp K. BUCHLING REGO, Wappingers Falls, NY (US); David Clifford LONG, Wappingers Falls, NY (US); Robert WEISS, LaGrangeville, NY (US); Felipe Andres VALENZUELA GAETE, Poughkeepsie, NY (US)

(21) Appl. No.: 18/754,778

(22) Filed: Jun. 26, 2024

(51) Int. Cl. H05K 3/00

(52) U.S. Cl. CPC H05K 3/0014; H05K 2203/0195

(57) ABSTRACT

Method and apparatus of forming a flex circuit to a three dimensional shape using pressurized airflow. In one embodiment, pressurized airflow creates an air flow between the forming fixture and the flex circuit which avoids or mitigates problems that arise during traditional methods of shaping the forming fixture. An air flow allows an even distribution of pressure that can more evenly shape the flex circuit to a desired shape. An air flow between the forming fixture and the flex circuit distributes pressure evenly.

### BACKGROUND

The present invention relates to flex circuits, and more specifically, to a three dimensional flex circuit forming process. Three dimensional flex circuits are printed circuit boards (PCBs) that combine the benefits of transitional flex circuits with the ability to conform to three dimensional shapes. These circuits can be made of flexible substrates such as polyimide or polyester, allowing them to bend as they are formed in a way that a traditional PCB may not. Such flexibility is advantageous in applications where space is limited. For example, the flexible design allows integration into devices with limited space, such as medical devices, wearable electronics, automobiles, etc.

Traditionally, the process of forming three dimensional flex circuits involves shaping it according to a mold. Forming flex circuits in this way is not always reliable however, as it can lead to cracks, unwanted sticking, and other issues of consistency in the circuit.

### SUMMARY

In embodiments of the current disclosure, a method for forming a flex circuit using a forming fixture is described. The method includes creating an airflow between a ram of the forming fixture and the flex circuit using pressurized air; and applying a force, using the ram, to shape the flex circuit while maintaining the airflow between the ram and the flex circuit.

In other embodiments of the current disclosure, a system is described. The system includes a ram; a base plate including a cavity; a pressurized air source configured to create an airflow between the ram and a flex circuit as the ram applies a force that deforms the flex circuit as the flex circuit extends into the cavity of the base plate.

### BRIEF DESCRIPTION OF THE DRAWINGS

FIG. 1 illustrates a module assembly which includes components that can render the module assembly a secure module assembly, according to some embodiments.

FIG. 2 illustrates a flat piece of the flex circuit before it is formed in a shape necessary to match that of the enclosure, according to some embodiments.

FIG. 3 illustrates the flat flex circuit in FIG. 2 has been formed in a forming fixture to form a cavity, according to some embodiments.

FIG. 4 illustrates the flex circuit of FIG. 3 has been trimmed to remove excess material, according to some embodiments.

FIG. 5 illustrates the trimmed flex circuit of FIG. 4 has been placed within the enclosure, according to some embodiments.

FIG. 6A illustrates the forming fixture before the flex circuit is formed, according to some embodiments.

FIG. 6B illustrates the forming fixture when it is closed as it forms the flex circuit, according to some embodiments.

FIG. 7 illustrates the airflow through a ram, according to some embodiments.

FIG. 8A illustrates the design of the ram, according to some embodiments.

FIG. 8B illustrates the perforated ram insert, according to some embodiments.

FIG. 9 illustrates a flow diagram for shaping the flex circuit, according to some embodiments.

### DETAILED DESCRIPTION

Three dimensional flex circuits can be formed using a forming fixture. The flex circuit can be molded to the shape of the forming fixture, providing its three dimensional shape. However, simply pressing a flex circuit to form to the shape of a forming fixture (e.g., a ram) presents problems. Friction between the forming fixture and the flex circuit itself, localized pressure, among other issues arising from direct contact between the forming fixture and the flex circuit, can cause the flex circuit to stretch unfavorably, not take to the expected shape, crack, or stick to the forming fixture.

Embodiments disclosed herein are directed toward a process of forming a flex circuit to a three dimensional shape using pressurized airflow. In one embodiment, pressurized airflow creates an air bearing between the forming fixture and the flex circuit which avoids or mitigates problems that arise during traditional methods of shaping the forming fixture. An air bearing allows an even distribution of pressure that can more evenly shape the flex circuit to a desired shape. An air bearing between the forming fixture and the flex circuit distributes pressure more evenly, as the friction between the flex circuit and the forming fixture is reduced. This improves the quality of shaping the flex circuit, the reliability of shaping the flex circuit, among other improvements.

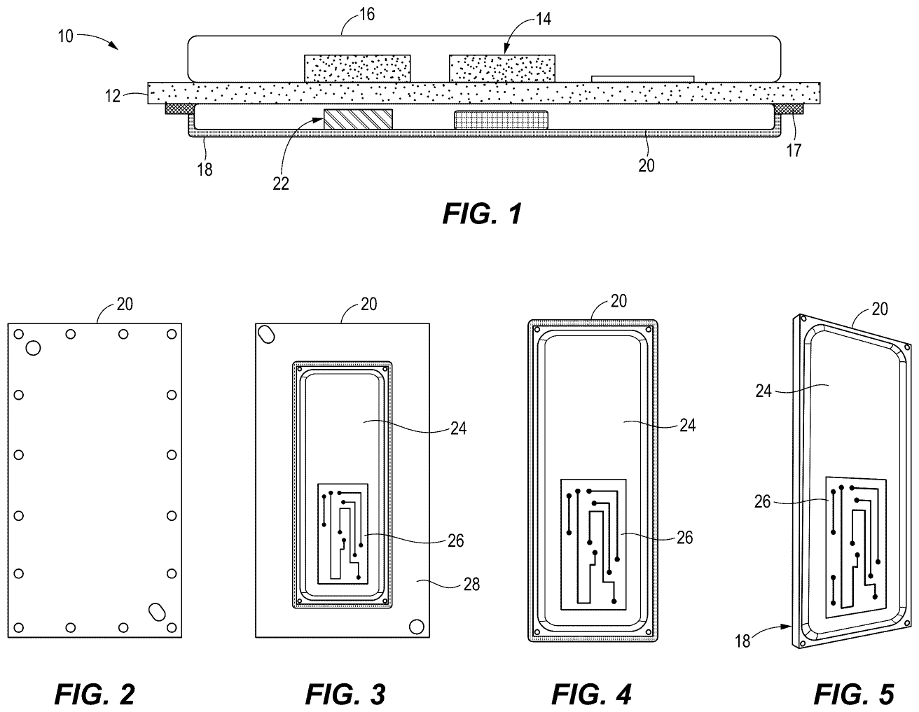

Referring to the drawings in more detail, and particularly referring to FIG. 1, there is illustrated a module assembly 10 which may also include components to render the module assembly 10 a secure module assembly.

The module assembly 10 includes a circuit board 12, such as a printed circuit board 12, on which may be mounted electronic components, generally indicated by 14. The particular electronic components 14 are unimportant to the present exemplary embodiments but may include, for the purpose of illustration and not limitation, semiconductor devices, resistors, capacitors and input/output devices. Enclosing the electronic components 14 may be a cover 16 which may be made from aluminum or copper or stainless steel, for example.

Below the circuit board 12 may be a tamper-resistant enclosure 18. The enclosure may be made from a metal such as aluminum or copper or stainless steel. The tamper-resistant enclosure 18 may have flange 17 which may be used to bond the tamper-resistant enclosure 18 to the circuit board 12. The bond (not shown) may be, for example, an adhesive. Within the enclosure 18 is a flex circuit 20 which is formed so as to match the profile of the enclosure 18 and essentially lines the interior surface of the enclosure 18. The flex circuit 20 may contain several layers and on one or more layers, there may be security circuits, such as serpentine circuits, that may be connected to tamper detection circuits. The tamper detection circuits may erase encryption keys or sensitive data, among other things, if an intrusion is detected, for example, if one or more of the tamper detection circuits is broken or disturbed. Located on the flex circuit 20 and/or the printed circuit board 12 may be electronic components, generally indicated by 22. Again these electronic components 22 may include, for the purpose of illustration and not limitation, semiconductor devices, resistors, capacitors and input/output devices.

In the module assembly 10, the enclosure 18 is a low profile design which uses in the exemplary embodiments to form the flex circuit 20 to match the profile of the enclosure 18. For the purpose of illustration and not limitation, the exterior height of the enclosure 18 may be 0.5 to 5 mm as measured from the point of attachment to the circuit board 12.

A flex circuit is a flexible circuit board that has been made by laying down a layer of insulating material followed by layers of additional insulating material having metallic circuitry, for example, copper, formed on the insulating material. Topping the flex circuit may be another layer of insulating material. The various layers may be bonded together by a nonconductive adhesive. For purposes of illustration, the insulating material may be Kapton® polyimide manufactured by E. I. du Pont de Nemours.

Referring now to FIGS. 2 to 5, there is illustrated the formation of the flex circuit 20. In FIG. 2, there is illustrated a flat piece of the flex circuit 20 before it is formed in a shape to match that of the enclosure 18. The flex circuit 20 is completed except for deforming into the desired shape. That is, the multiple layers of circuitry have been formed and bonded together to form the flex circuit 20. Tooling holes are shown along the perimeter of the flex circuit 20.

For the purpose of illustration and not limitation, the flex circuit 20 may have four layers of copper traces fine pitch copper traces on each layer. The insulating material may be Kapton® polyimide.

Referring now to FIG. 3, the flat flex circuit 20 in FIG. 2 has been formed in a forming fixture (to be described hereafter) to form a cavity 24. FIG. 3 is an enlarged view of FIG. 2 so that the tooling holes on the perimeter of the flex circuit 20 are not shown. Within cavity 24 is located the electronic circuitry 26 for the flex circuit 20. The electronic circuitry 26 may include security circuits, such as serpentine circuits, that may be connected to tamper detection circuits. The electronic circuitry 26 is covered by a protective layer (not shown) to protect the electronic circuitry 26 from damage. The protective layer has no security value other than to protect the electronic circuitry 26 from physical or electrical damage.

The original flat portion 28 of the flex circuit 20 is no longer needed after the deformation step in FIG. 3. Most of the excess flat portion 28 of the flex circuit 20 is then cut off. The flex circuit 20 without the excess flat portion 28 is shown in FIG. 4.

Referring now to FIG. 5, the remaining portion of the flex circuit 20 with the cavity 24 is placed within the enclosure 18. FIG. 5 has been slightly rotated to show a side portion of the enclosure 18. Before placing the flex circuit 20 within the enclosure 18, adhesive (not shown) may be applied to the flex circuit 20 and/or the interior of the enclosure 18 so that the flex circuit 20 may be bonded to the enclosure 18. Any electronic components 22 (FIG. 1) may be joined to the flex circuit 20 and then the enclosure 18 with the flex circuit 20 may be bonded, such as by an adhesive, to the circuit board 12.

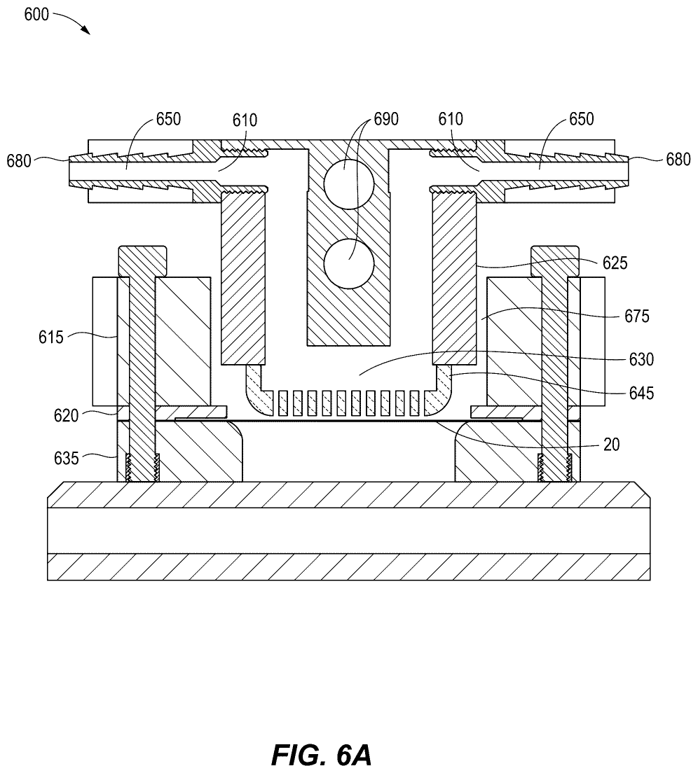

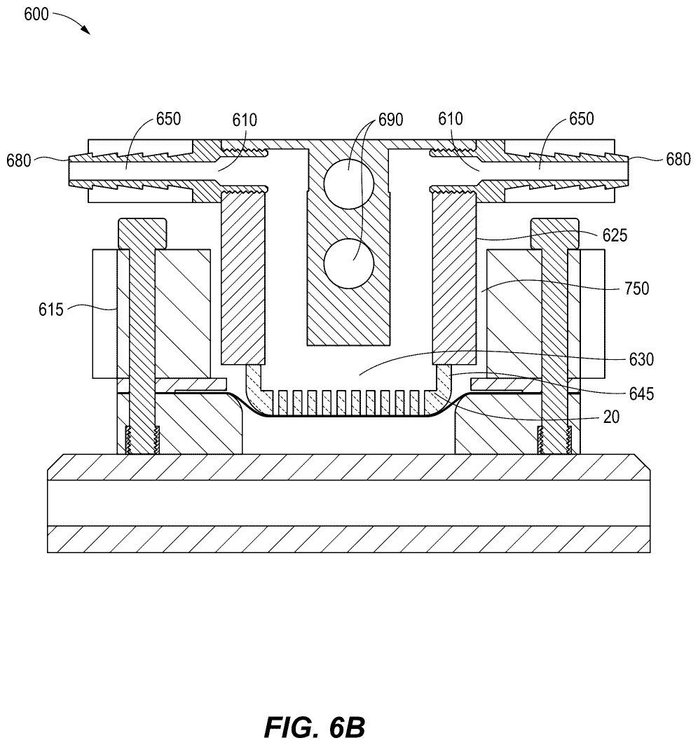

Referring now to FIG. 6A and FIG. 6B, FIG. 6A depicts the forming fixture 600 before the flex circuit 20 is formed, and FIG. 6B depicts the forming fixture's 600 position as closed, as it forms the flex circuit 20. The forming fixture 600 may also be referred to as a 3-D forming fixture. As shown in FIG. 6A the flex circuit 20 lays flat on top of the base plate 635. In FIG. 6B, the flex circuit 20 is pushed into the base plate 635 by the ram insert 645 of the ram 625. As the flex circuit 20 is pushed into the base plate 635 for shaping, pressurized air (from a pressurized air source 680) flows are introduced at the air inlets 650 disposed on either side of the ram 625. The air inlets 650 allow airflow to flow though the ram 625 where it reaches the hollow upper chamber 630 of the ram insert 645 and pushes through the ram insert 645, creating an air passageway between the ram 625 and the flex circuit 20. The ram 625 may have passageways. These passageways can facilitate airflow from the air inlets 650 through the ram 625. Airflow creating the air bearing between the flex circuit 20 and the ram insert 645 may exit the forming fixture 600 through the exit tunneling 675. The holes 690 of the forming fixture allow for heating and cooling by liquid, electric heating elements, among other things. Also, the forming fixture includes barbed housings for tubing at the fluid inlets 610 for receiving the pressurized air.

Also included on the forming fixture 600 is a wrinkle reducer 620 and a clamp 615 which together clamp on the flex circuit 20, helping provide a constant applied force while the flex circuit 20 is being formed. That is, a periphery of the flex circuit can be clamped while the middle of the flex circuit is formed. The wrinkle reducer 620 helps clamp the flex circuit 20 on the perimeter while not clamping the flex circuit 20 near the forming area. This allows the flex circuit 20 to stretch where needed. The wrinkle reducer 620 has a slight height change between the clamping area and the stretching area. This height change allows the flex circuit 20 to stretch where desired while preventing wrinkles from forming, as the height is being restricted by the wrinkle reducer 620.

The base plate 635 has an alignment for pins for aligning the other components of the forming fixture 600 and heaters for heating the base plate 635. The base plate 635 may also include a cavity into which the flex circuit 20 will be formed.

As shown in FIG. 6A, the flat flex circuit 20 in FIG. 6A is placed on top of the base plate 635. Alignment pins may be used to align the flex circuit 20 to the correct position on the base plate 635. The portion of the flex circuit 20 within the cavity is the part of the flex circuit 20 that may be molded to form its 3-D shape.

A wrinkle reducer 620 may be placed on the flex circuit 20. The alignment pins may be used to align the wrinkle reducer 620 to the correct position on the base plate 635 and also correctly align the wrinkle reducer 620 with respect to the flex circuit 20. The wrinkle reducer 620 may include a cut-out portion which may correspond to the shape of the cavity in the base plate 635. The wrinkle reducer 620 limits the wrinkles that may be formed during the shaping of the flex circuit 20. These wrinkles are usually formed in the corners.

The air inlets 650 receive pressurized airflow which can then flow through the ram 625. The pressurized airflow helps create a low friction surface by maintaining an air cushion (e.g., air bearings) between the ram 625 and the flex circuit 20 with the pressurized air, improving the process of shaping the flex circuit 20. Pressurized air flows through the ram 625 until reaching a chamber at the bottom of the ram 625. This chamber is a hollow upper chamber 630 of the ram insert 645 which evenly distributes the airflow through the ram insert 645. In one embodiment, the ram insert 645 is perforated to allow such airflow, creating the low friction surface between the ram insert 645 and the flex circuit 20 as the flex circuit 20 is shaped.

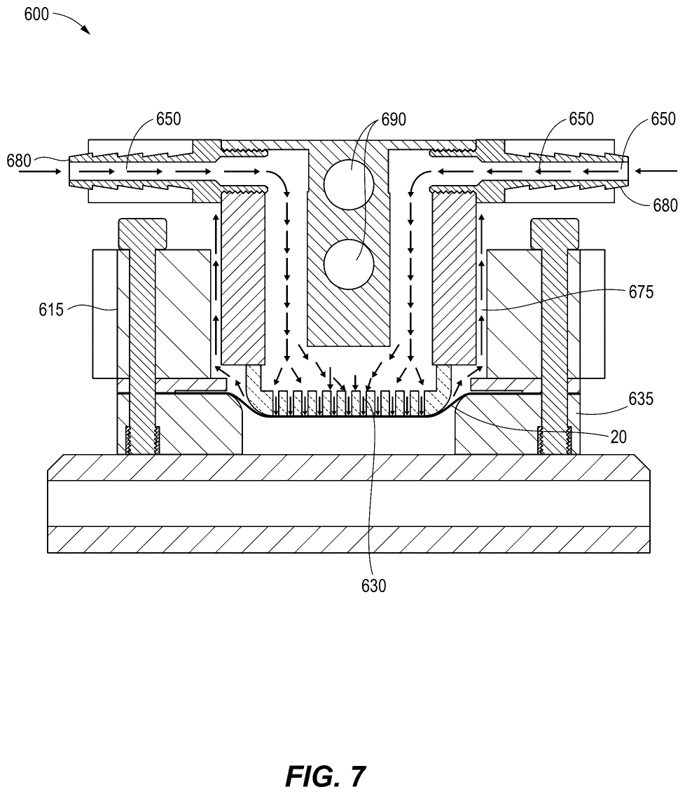

FIG. 7 illustrates the pressurized airflow through the ram 625. The airflow starts at the air inlets 650. Airflow may be at various temperatures at various pressures. For example, they may change according to process parameters used for the flex materials, or the desired 3-D shape. These temperatures and pressures could stay constant, or they could change throughout the flex circuit 20 shaping process. The compressed air flows into the ram 625 through the air inlets 650. In some embodiments initiating compressed airflow into the ram 625 through the air inlets is done prior to applying force to the ram 625, and in other embodiments initiating compressed airflow into the ram 625 through the air inlets is done simultaneously with applying force to the ram 625. The pressurized air flows through the ram 625 until reaching the hollow upper chamber 630 of the ram insert 645 at the bottom of the ram 625. The ram insert 645 can be an additional attachment to the ram 625 or designed as part of the ram 625. The airflow then pushes through the perforated surface of the ram insert 645 creating air bearings between the ram insert 645 and the flex circuit 20. Airflow creating the air bearings may exit the forming fixture 600 through the exit tunneling 675. The exit tunneling 675 ensures the pressurized air creating the bearing is not too high. The air bearings reduce friction between the ram insert 645 of the ram 625 and the flex circuit 20, allowing the flex circuit 20 to stretch in a non-localized manner from the pressurized airflow as force is applied to the ram 625.

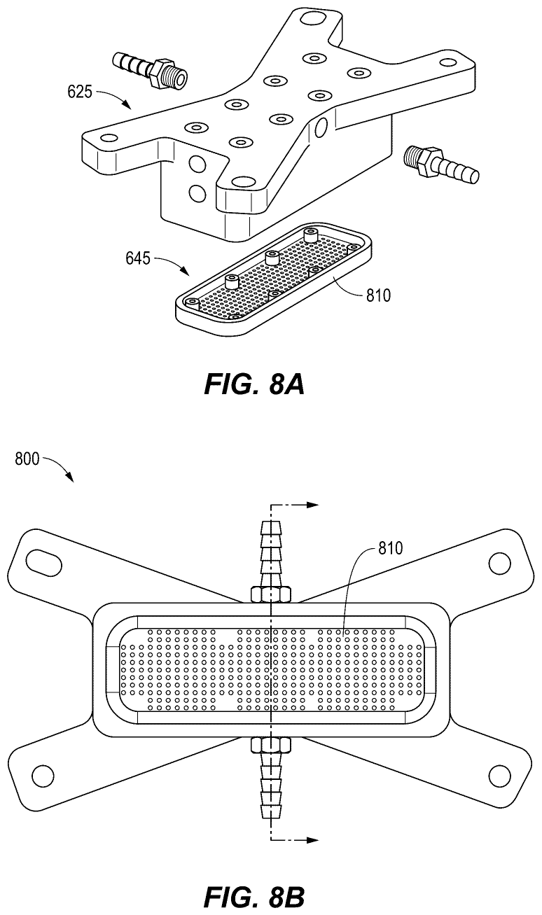

FIG. 8A depicts the body of the ram 625, showing also where the ram insert 645 should be included and where the air inlets 650 can be attached. Inlets refer to tubes, valves, screws, etc. through which fluids or gasses can flow in and out of. FIG. 8B depicts the design of the ram insert 645 in a direction looking up towards the insert 645 and the ram 625. This structure could be made as one part or as multiple parts. One way of making the one or many structures includes but is not limited to alienate manufacturing.

The ram 625 may move freely up and down within the forming fixture 600. Along with the internal air inlets 650 and fluid inlets 610, the ram 625 may also include more cavities running through it for temperature specific fluids or gas, removing unnecessary weight, etc. The cutouts in the ram 625 can enable pressurized air to travel through the ram 625 from at least one air inlet 650, and into the hollow upper chamber 630 of the ram insert 645 before exiting through the perforated surface of the ram insert 645.

The bottom of the ram insert 645 is what contacts the surface of the flex circuit 20 as the flex circuit 20 is formed to the shape of the cavity of the forming fixture 600. The friction between the bottom of the ram insert 645 and the flex circuit 20 is decreased as a thin cushion of the pressurized air flowing through the ram 625 is spread evenly through the perforated surface of the ram insert 645 as it moves closer to the flex circuit 20 during shaping. The thin cushion of air spreads evenly across the surface area though the ram insert 645. In some embodiments, the ram insert 645 has a plurality of holes 810 allowing the pressurized airflow to distribute through the holes 810, across its surface area between the ram and the flex circuit. The holes 810 may be drilled according to a plurality of patterns. In other embodiments, the ram insert 645 is a porous material that already allows pressurized airflow to move evenly though without holes 810.

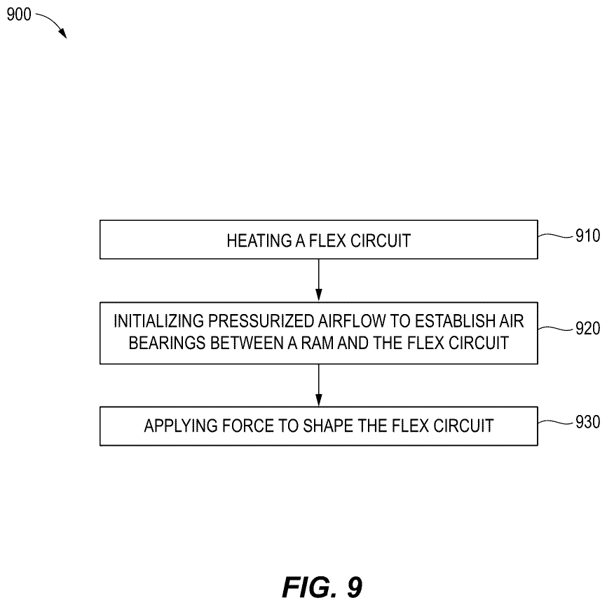

With reference now to FIG. 9, the flow diagram 900 describes the process of forming the flex circuit 20.

At block 910, a forming fixture heats the flex circuit 20. The process of heating the flex circuit 20 can include heating the forming fixture 600 to a predetermined temperature. In one exemplary embodiment, the heating temperature may be about 100-150° C. The upper limit may be chosen to avoid material damage to the flex circuit 20.

The forming fixture 600 may be heated by heating the base plate 635 with heaters and/or running a hot fluid through a designated cavity in the ram 625. The temperature may be monitored by thermocouples in multiple places in the forming fixture 600. It may be desirable to let the forming fixture 600 sit at the predetermined temperature for a period of time, for example 5 minutes, to assure that the forming fixture 600 has been evenly heated.

At block 920, a user initializes pressurized airflow through the air inlets 650. This pressurized airflow flows through the ram 625, collecting at the hollow upper chamber 630 of the ram insert 645 to establish air bearing between the ram 625 and the flex circuit 20 as the ram 625 pushed on the flex circuit 20. In one exemplary embodiment, the flex circuit 20 may be clamped between the wrinkle reducer 620 and the base plate 635. The compressed air may then be initiated to flow through the ram's air inlets 650.

At block 930, the ram 625 applies a force to shape the flex circuit. As the ram 625 moves downward, a cushion of compressed air is formed between the ram insert 645 and the flex circuit 20 which deforms the flex circuit 20 into the cavity in the base plate 635. That is, the ram insert 645 may not directly contact the flex circuit 20 because of the air cushion/air bearings formed by the pressurized air, although it may directly contact the circuit 20 in some locations.

It may be desirable to move the ram 625 downwardly at a constant rate until the ram 625 reaches its maximum limit of travel. The air gap between the ram insert 645 and the flex circuit 20 may be held for a predetermined amount of time, for example 5 minutes, while the forming fixture 600 is heated at the predetermined temperature. The forming fixture 600 may be cooled to a second predetermined temperature with the pressurized air field still in contact with the formed flex circuit 20. The second predetermined temperature may be, for example, less than 100° C. or between 50° C. and 150° C. Temperature is advantageous to avoid forming steam during cooling of the forming fixture 600.

After the forming fixture 600 has reached the second predetermined temperature, the ram 625 may be raised. The flex circuit 20 may be removed from the forming fixture 600. In one exemplary embodiment, the forming fixture 600 may be cooled to room temperature by water prior to removal of the flex circuit 20 from the forming fixture 600. The water can flow through the barbed housing for tubing at the fluid inlet 610. The flex circuit 20 may now have an indent resulting from forming the flex circuit 20 into the cavity in the base plate 635 and a flat portion surrounding the indented portion as shown in FIGS. 3-5.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the following, reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

While the foregoing is directed to embodiments of the present invention, other and further embodiments of the invention may be devised without departing from the basic scope thereof, and the scope thereof is determined by the claims that follow.

What is claimed is:

1. A method for forming a flex circuit using a forming fixture, the method comprising:
creating an airflow between a ram of the forming fixture and the flex circuit using pressurized air; and
applying a force, using the ram, to shape the flex circuit while maintaining the airflow between the ram and the flex circuit.

2. The method of claim 1, wherein the ram comprises a plurality of holes allowing the airflow to distribute through the holes, across its surface area, between the ram and the flex circuit.

3. The method of claim 2, wherein the airflow flows through the plurality of holes of the ram, across the surface area of the ram, and reduces friction between the ram and the flex circuit, allowing the flex circuit to stretch in a non-localized manner from the airflow as the force is applied to the ram.

4. The method of claim 1 wherein the flex circuit is shaped to the form of a cavity of the forming fixture as pressure is applied to the ram.

5. The method of claim 1, further comprising:
heating the flex circuit, wherein heating the flex circuit comprises heating the forming fixture where the flex circuit sits as the flex circuit is shaped.

6. The method of claim 1, wherein the flex circuit is formed to a 3-dimensional (3-D) shape from an initial 2-dimensional (2-D) shape.

7. The method of claim 1, wherein a periphery of the flex circuit is clamped while a middle of the flex circuit is deformed by the ram.

8. The method of claim 1, wherein the forming fixture comprises air inlets, wherein the air inlets allow air to flow into the forming fixture.

9. The method of claim 8, wherein the ram comprises passageways, wherein the passageways facilitate airflow from the air inlets through the ram.

10. The method of claim 1, wherein the airflow may exit the forming fixture through exit tunneling.

11. A system, comprising:
a ram;
a base plate comprising a cavity;
a pressurized air source configured to create an airflow between the ram and a flex circuit as the ram applies a force that deforms the flex circuit as the flex circuit extends into the cavity of the base plate.

12. The system of claim 11, wherein the ram comprises a plurality of holes allowing the airflow to distribute through the holes, across its surface area, between the ram and the flex circuit.

13. The system of claim 12, wherein the airflow flows through the holes of the ram, across the surface area of the ram, and reduces friction between the ram and the flex circuit, allowing the flex circuit to stretch in a non-localized manner from the airflow as the force is applied to the ram.

14. The system of claim 11, wherein the flex circuit is shaped to the form of the cavity as pressure is applied to the ram.

15. The system of claim 11, wherein the flex circuit is heated, wherein an operation of heating the flex circuit comprises heating a flex forming fixture where the flex circuit sits as the flex circuit is shaped.

16. The system of claim 11, wherein the flex circuit is formed to a 3-D shape from an initial 2-D shape.

17. The system of claim 11, further comprising:
a clamp configured to clamp a periphery of the flex circuit to the base plate when the ram is deforming a middle of the flex circuit.

18. The system of claim 11, wherein the forming fixture comprises air inlets, wherein the air inlets allow air to flow into the forming fixture.

19. The system of claim 18, wherein the ram comprises passageways, wherein the passageways facilitate airflow from the air inlets through the ram.

20. The system of claim 11, wherein the airflow may exit the forming fixture through exit tunneling.
